(19) United States
(12) Patent Application Publication
(10) Pub. No.: US 2024/0194565 A1
(43) Pub. Date: Jun. 13, 2024

(54) COOLING SYSTEM FOR A SEMICONDUCTOR DEVICE ASSEMBLY

(71) Applicant: Micron Technology, Inc., Boise, ID (US)

(72) Inventors: Ravi Kumar Kollipara, Puppalaguda (IN); Suresh Reddy Yarragunta, Bangalore (IN)

(21) Appl. No.: 18/514,763

(22) Filed: Nov. 20, 2023

Related U.S. Application Data
(60) Provisional application No. 63/430,991, filed on Dec. 7, 2022.

(51) Int. Cl. H01L 23/473; H01L 21/56; H01L 25/18; H10B 80/00

(52) U.S. Cl. CPC H01L 23/473; H01L 21/56; H01L 25/18; H10B 80/00; H01L 24/16

(57) ABSTRACT

A semiconductor device assembly is provided that includes a cooling system. The semiconductor device assembly includes a semiconductor die assembled onto a substrate. A channel is disposed at a back side of the semiconductor die to enable fluid to flow through the channel and cause heat to transfer from the semiconductor die to the fluid. The fluid is received through an inlet to enable the fluid to be flowed through the channel. After the fluid is flowed through the channel, the fluid is expelled through an outlet. In this way, a compact and effective cooling system for a semiconductor device assembly may be implemented.

### CROSS-REFERENCE TO RELATED APPLICATION(S)

The present application claims priority to U.S. Provisional Patent Application No. 63/430,991, filed Dec. 7, 2022, the disclosure of which is incorporated herein by reference in its entirety.

### TECHNICAL FIELD

The present disclosure generally relates to semiconductor device assemblies, and more particularly relates to a cooling system for a semiconductor device assembly.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1 illustrates a simplified schematic perspective view of a semiconductor device assembly in accordance with an embodiment of the present technology.

FIG. 2 illustrates a simplified schematic partial plan view of a semiconductor device assembly in accordance with an embodiment of the present technology.

FIG. 3A-7B illustrates simplified schematic partial plan views and cross-sectional views of semiconductor device assemblies through a series of stages for fabricating a semiconductor device assembly in accordance with an embodiment of the present technology.

FIG. 8 illustrates a simplified schematic partial plan view of a semiconductor device assembly in accordance with an embodiment of the present technology.

FIG. 9 illustrates a simplified schematic partial plan view of a semiconductor device assembly in accordance with an embodiment of the present technology.

FIG. 10 illustrates a schematic view showing a system that includes a semiconductor device assembly configured in accordance with an embodiment of the present technology.

FIG. 11 illustrates a method for making a semiconductor device assembly in accordance with an embodiment of the present technology.

### DETAILED DESCRIPTION

The capability of semiconductor devices has continued to improve over the years, giving rise to a variety of new applications. Many of these applications, for example, artificial intelligence (AI) and machine-learning (ML) applications, require a large number of computations, which in turn require large power supplies. These large power supplies may produce heat in the semiconductor device, which can overheat the device and impact device performance. As a result, many semiconductor device assemblies implement a cooling system to decrease the thermal resistance of a semiconductor device. Some cooling systems may utilize a heat sink to remove heat from the semiconductor device and mitigate overheating. These cooling systems, however, may be inadequate to support power-intensive applications, such as AI and ML applications. Moreover, these cooling systems may be too large to fit into low-profile semiconductor devices, for example, devices that comport with the Peripheral Component Interconnect Express (PCIe) standard.

To resolve these deficiencies and others, the present technology relates to a cooling system for a semiconductor device. A semiconductor device assembly is provided that includes a semiconductor die assembled onto a substrate. A channel is disposed at a back side of the semiconductor die to enable fluid to flow through the channel and cause heat to transfer from the semiconductor die to the fluid. The fluid is received through an inlet to enable the fluid to be flowed through the channel. After the fluid is flowed through the channel, the fluid is expelled through an outlet. In this way, a compact and effective cooling system for a semiconductor device assembly may be implemented.

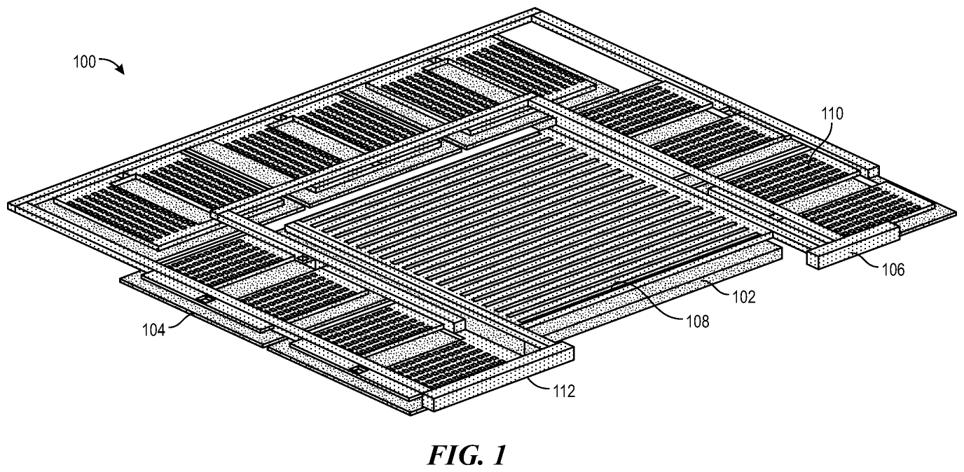

FIG. 1 illustrates a simplified schematic perspective view of a semiconductor device assembly 100 in accordance with an embodiment of the present technology. The semiconductor device assembly 100 may include one or more packaged semiconductor devices implementing one or more semiconductor dies. As illustrated, the semiconductor device assembly 100 includes a processor 102 electrically coupled with a plurality of memory devices 104. The processor 102 may include one or more logic semiconductor dies and the memory devices 104 may include one or more memory dies. The processor 102 and the memory devices 104 may be assembled onto a substrate to provide external connectivity (e.g., power, ground, and input/output (I/O) signals) to the processor 102 and the memory devices 104 through traces, lines, vias, and other connection structures in the substrate.

In aspects, the processor 102 may be a central processing unit (CPU), a graphics processing unit (GPU), an integrated circuit (IC), a System-on-Chip (SoC), a field-programmable gate array (FPGA) device, or any other logic device. The memory devices 104 may include memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). Although illustrated in a particular configuration, the semiconductor device assembly 100 may include a different arrangement of logic or memory devices. For example, the processor 102 may be replaced with one or more logic dies, logic die packages, other semiconductor die packages, or the like. Similarly, the memory devices 104 may be replaced with one or more memory dies, memory die packages, other semiconductor die packages, or the like. In aspects, the semiconductor device assembly 100 may be a graphics card that includes a GPU and memory dies therewith (e.g., graphical double-data rate (GDDR) synchronous dynamic random access memory (SDRAM)). The semiconductor device assembly 100 may be a low-profile device, for example, a device that comports with at least one PCIe standard (e.g., a PCIe form factor).

The semiconductor device assembly 100 includes a cooling system that couples with the processor 102 and the memory devices 104. The cooling system may include an input manifold 106 that provides fluid (e.g., water, coolant, etc.) to the processor 102 and the memory devices 104. The fluid may be flowed through a channel 108 disposed at the processor 102 and channels 110 disposed at the semiconductor dies of the memory devices 104. As the fluid is flowed through the channel 108 and the channels 110, heat may transfer from the processor 102 and the semiconductor dies within the memory devices 104 to the fluid. The heated fluid may be expelled through an output manifold 112 after it has been flowed through the channels 108 or the channels 110. In aspects, the input manifold 106 and the output manifold 112 may be discrete manifolds that are only connected through the channel 108 and the channels 110. In this way, the fluid may travel along the input manifold 106 until it is flowed through any one of the channel 108 or the channels 110. Once the fluid has flowed through the channel 108 or any of the channels 110, the fluid may be provided to the output manifold 112 where it is expelled. As a result, the fluid provided to any of the channel 108 or the channels 110 may not be preheated, for example, due to heat transfer during a flowing of the fluid through a different one of the channel 108 or the channels 110.

The input manifold 106 may be designed to provide more fluid to the processor 102 than to the memory devices 104. For example, the channel 108 or the portions of the input manifold 106 providing fluid to the channel 108 may be designed to be less resistant to fluid flow than the channels 110 or the portions of the input manifold 106 providing fluid to the channels 110. A plurality of structures (e.g., pillar-shaped structures) may extend through the channels 110 to accelerate the flow through the channels 110 (e.g., by reducing pressure drop across the channel). The plurality of structures may additionally increase the area of the surface at which heat transfer may occur. The plurality of structures may be arranged in a grid throughout the channels 110. Structures may similarly extend through the channel 108 to create rows through which the fluid may flow. The channel 108 may provide a larger area for the fluid to flow through and a larger surface area for heat transfer to occur. The memory devices 104 may include an inlet at which the input manifold 106 may couple to provide fluid to the channels 110 and an outlet at which the output manifold 112 may couple to expel fluid after it has been flowed through the channels 110. The channel 108 may directly couple with the input manifold 106. Therefore, the fluid flow may be optimized to provide more fluid to the most power-intensive areas (e.g., the processor 102) of the semiconductor device assembly 100.

In aspects, the channels 110 may be die-level channels that are implemented to facilitate heat transfer at each die within the memory devices 104. For example, the memory devices 104 (e.g., or any other packaged semiconductor device) may include multiple dies (e.g., as illustrated, two-die packages). Channels 110 may be implemented at each of the semiconductor dies within the memory devices 104. The channels 110 within each package may couple to a common inlet and a common outlet. In this way, the cooling system may provide die-level cooling integrated within each package, and the cooling system may be optimized for each die within the package while still maintaining a scalable design that is consistent across packages. Additionally, the cooling system may optimize flow to the most power-intensive areas. The resulting semiconductor device assembly 100 may have a thermal resistance less than 0.05 degrees Celsius per Watt.

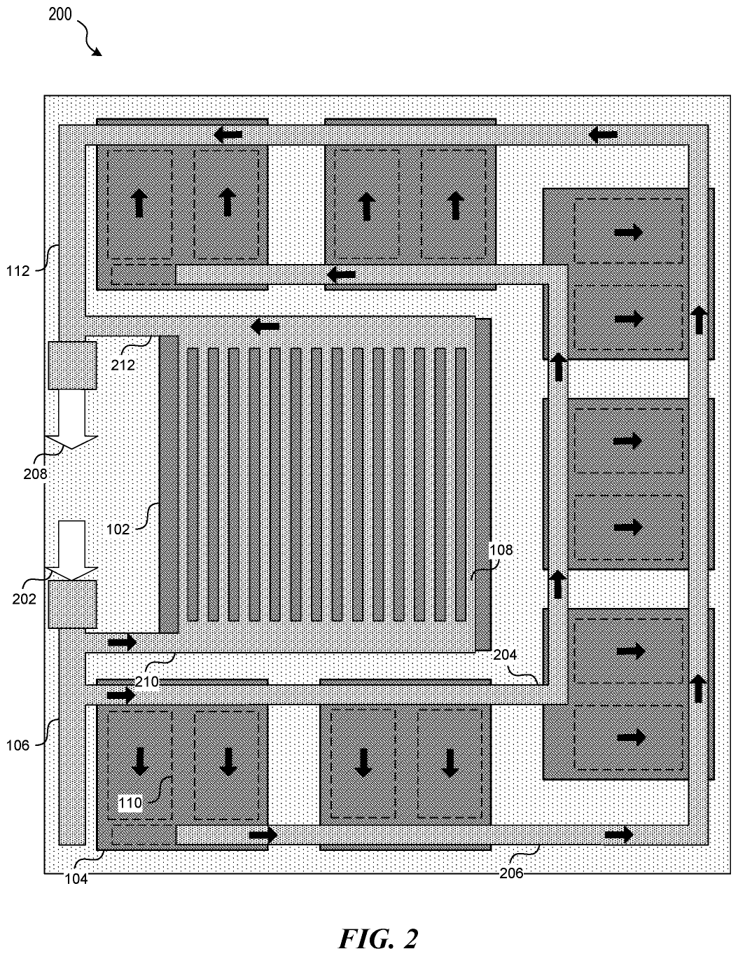

FIG. 2 illustrates a simplified schematic partial plan view of a semiconductor device assembly 200 in accordance with an embodiment of the present technology. As illustrated, the input manifold 106 receives fluid from a fluid source (indicated by arrow 202). The input manifold 106 includes an input fluid pipeline 204 to provide fluid to memory devices 104 (e.g., or any other packaged semiconductor device) through inlets in the memory devices 104. The fluid may flow through channels 110 to cause heat to transfer from the semiconductor dies implemented within the memory devices 104 to the fluid. The heated fluid is provided to an output fluid line 206 of the output manifold 112 through outlets in the memory devices 104 where it is expelled into a fluid sink (indicated by arrow 208). The channels 110 may be implemented at each semiconductor die within the memory devices 104. The channels 110 may be coupled to a common inlet and outlet to enable fluid to flow in and out of the memory devices. The input manifold 106 may include an input fluid line 210 to provide fluid to the channel 108 disposed at the processor 102. The fluid may be flowed through the channel 108 to an output fluid line 212 of the output manifold 112 where it is expelled to the fluid sink.

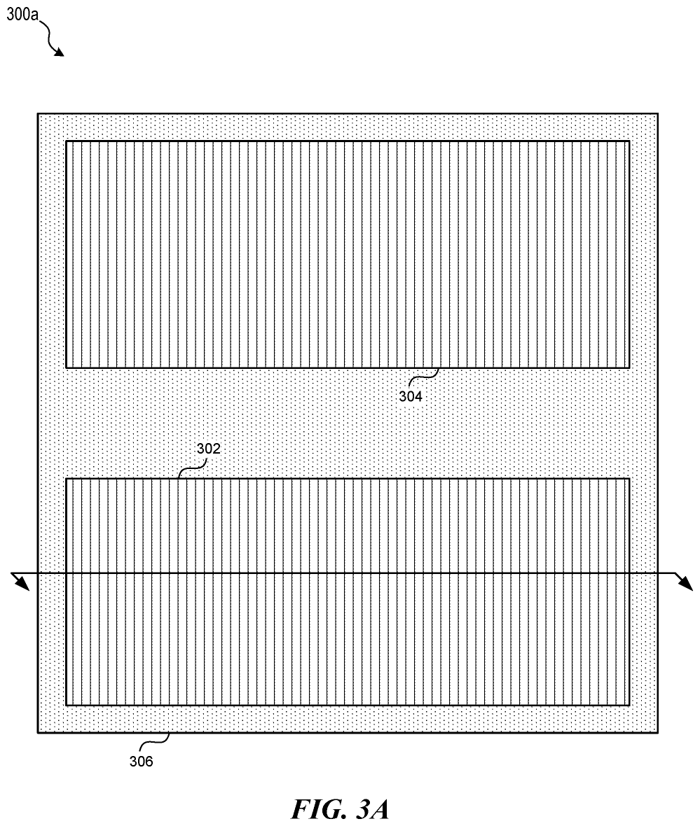

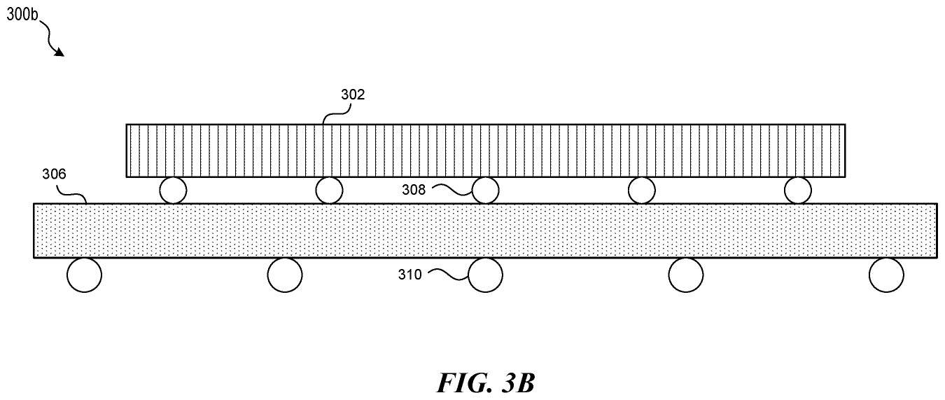

This disclosure now turns to details of a packaged semiconductor device (e.g., the memory devices 104 of FIG. 1) that may implement at least a portion of a cooling system for a semiconductor device. FIGS. 3A and 3B illustrate a stage for providing one or more semiconductor dies coupled to a substrate. Specifically, FIG. 3A illustrates a simplified schematic partial plan view 300a of a semiconductor device assembly in accordance with an embodiment of the present technology. As illustrated, a first semiconductor die 302 and a second semiconductor die 304 are laterally spaced from one another (e.g., at a top and a bottom as illustrated) on the substrate 306. The semiconductor die 302 and the semiconductor die 304 may be assembled onto the substrate 306 in a flip-chip arrangement (e.g., with a back surface of the semiconductor die 302 and a back surface of the semiconductor die 304 facing away from the substrate 306). Although illustrated as a two-die package, the semiconductor device assembly may have more or less semiconductor dies, for example, one, three, four, five, ten, etc.

FIG. 3B illustrates a simplified schematic cross-sectional view 300b (e.g., along the cross-section illustrated in FIG. 3A) of a semiconductor device assembly in accordance with an embodiment of the present technology. As illustrated, the semiconductor die 302 is assembled onto the substrate 306 in a flip-chip arrangement. Interconnects 308 (e.g., solder joints, conductive pillars, etc.) are formed between contacts on the substrate 306 and corresponding pads on the semiconductor die 302). The substrate 306 can further include package-level contact pads (e.g., with solder balls 310 thereat) for providing external connectivity to the semiconductor die 302 (e.g., power, ground, and I/O signals) through traces, lines, vias, and other electrical connection structures (not illustrated) in the substrate 306 that electrically connect the package-level contact pads at the lower surface to the contacts at the upper surface.

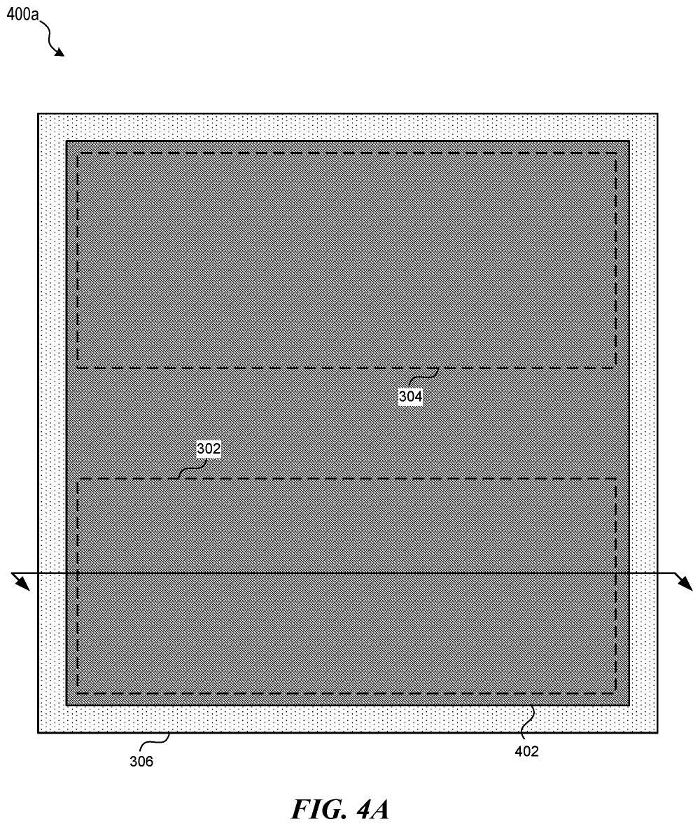

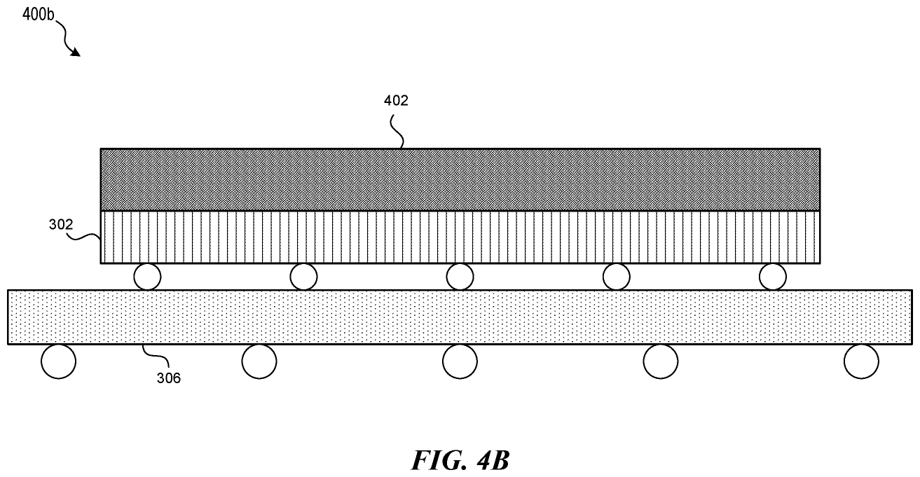

FIGS. 4A and 4B illustrate a stage for disposing a dielectric material at least at a back surface of the semiconductor dies. Specifically, FIG. 4A illustrates a simplified schematic partial plan view 400a of a semiconductor device assembly in accordance with an embodiment of the present technology, and FIG. 4B illustrates a simplified schematic cross-sectional view 400b (e.g., along the cross-section illustrated in FIG. 4A) of a semiconductor device assembly in accordance with an embodiment of the present technology. As can be seen with reference to FIGS. 4A and 4B, a layer of dielectric material 402 (e.g., silicon oxide, silicon nitride, silicon carbide, silicon carbon nitride, etc.) is disposed at a back surface of the semiconductor die 302 (covered by the dielectric material 402 and illustrated using dotted line in FIG. 4A). In some implementations, the layer of dielectric material 402 may additionally be disposed at semiconductor die 304 (e.g., covered by the dielectric material 402 and illustrated using dotted line in FIG. 4A). The layer of dielectric material 402 may be disposed at a substrate 306 between the semiconductor die 302 and the semiconductor die 304. In some cases, the layer of dielectric material 402 may extend beyond the back surface of the semiconductor die 302 or the semiconductor die 304. In aspects, the layer of dielectric material 402 may be deposited at the substrate 306 surrounding the semiconductor die 302 or the semiconductor die 304. Alternatively, the layer of dielectric material 402 may be disposed at the substrate 306 only between the semiconductor die 302 and the semiconductor die 304. In aspects, the dielectric material 402 may include silicon oxide. The dielectric material 402 may be deposited through any appropriate technique, for example, chemical vapor deposition, physical vapor deposition, atomic layer deposition, plating, electroless plating, or spin coating.

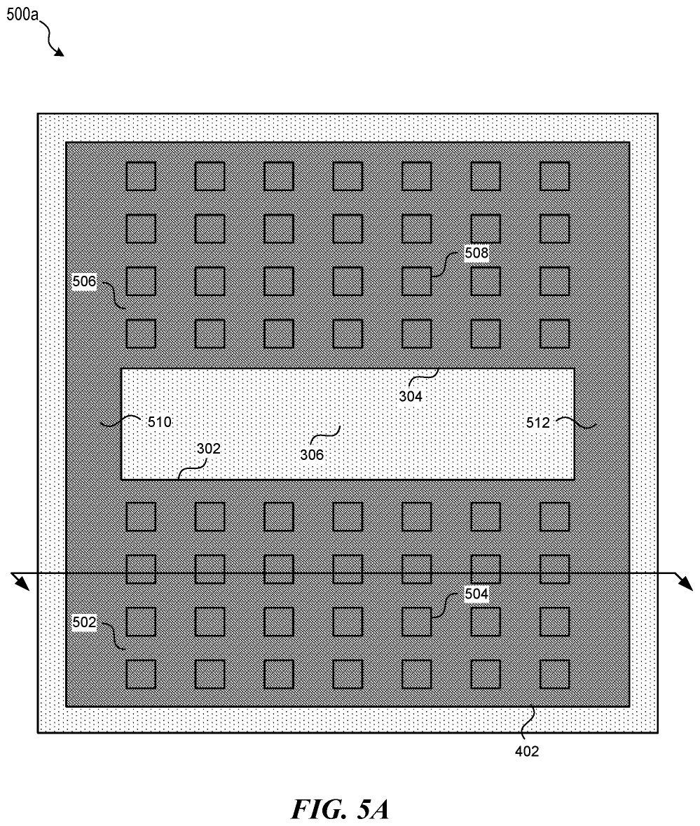

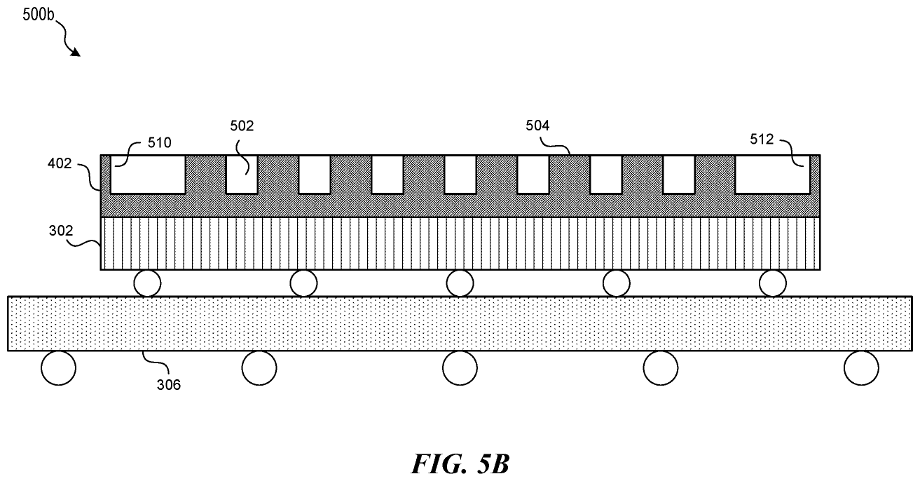

FIGS. 5A and 5B illustrate a stage for etching the dielectric material at least at a back surface of the semiconductor dies. Specifically, FIG. 5A illustrates a simplified schematic partial plan view 500a of a semiconductor device assembly in accordance with an embodiment of the present technology, and FIG. 5B illustrates a simplified schematic cross-sectional view 500b (e.g., along the cross-section illustrated in FIG. 5A) of a semiconductor device assembly in accordance with an embodiment of the present technology. The dielectric material 402 may be etched to create a channel 502 at a back surface of the semiconductor die 302. The channel 502 may enable fluid to be flowed through the channel 502 to cause heat to transfer from the semiconductor die 302 to the fluid through the back surface of the semiconductor die 302. The dielectric material 402 may be etched to create a plurality of structures 504 (e.g., composed of the dielectric material 402) that extend through the channel 502. The plurality of structures 504 may be pillar-shaped structures or be arranged in a grid throughout the channel 502. When fluid is flowed through the channel 502, the plurality of structures 504 may accelerate a flow of the fluid through the channel 502. The plurality of structures 504 may create obstructions in the channel 502 to distribute the fluid throughout the channel 502 and increase the surface area available for heat transfer. Although illustrated in FIG. 5B as having a bottom surface made from the dielectric material 402, the dielectric material 402 may be etched down to the back surface of the semiconductor die 302 to create the channel 502 defined at a bottom surface by the back surface of the semiconductor die 302. Although not illustrated in this way, the dielectric material 402 and the channel 502 etched therein may extend beyond the semiconductor die 302.

The dielectric material 402 may be similarly disposed at a back surface of the semiconductor die 304. The dielectric material 402 may be etched to create a channel 506 that enables fluid to be flowed through the channel 506 to cause heat to transfer from the semiconductor die 304 to the fluid through the back surface of the semiconductor die 304. The channel 506 may similarly be etched to create a plurality of structures 508 that extend through the channel 506. The channel 506 and the plurality of structures 508 may be created similar to the channel 502 and the plurality of structures 504. For example, the dielectric material 402 may be removed through plasma etching, wet etching, chemical-mechanical planarization, or any other technique. Similar to the plurality of structures 504 extending through the channel 502, the plurality of structures 508 may accelerate the fluid flow through the channel 506, distribute the fluid throughout the channel 506, provide a larger area for heat transfer, or maintain a pressure through the channel 506 (e.g., prevent pressure drops). In this way, the channel 502 and the channel 506 may be optimized for die-level cooling.

The dielectric material 402 may be etched between the semiconductor die 302 and the semiconductor die 304 to create an input channel 510 and an output channel 512 between the semiconductor dies. The input channel 510 may provide fluid to be flowed through the channel 502 and the channel 506. The output channel 512 may expel the fluid after it has been flowed through the channel 502 or the channel 506. The input channel 510 and the output channel 512 may be common channels coupled to the channel 502 and the channel 506 on the semiconductor die 302 and the semiconductor die 304. Thus, the cooling system may be optimized at the die level by creating individual channels (e.g., channel 502 and channel 506) at the semiconductor dies, while enabling fluid to be provided at the package level. The input channel 510 and the output channel 512 may be created by etching the dielectric material 402 disposed between the semiconductor die 302 and the semiconductor die 304. The dielectric material 402 may be etched between the semiconductor dies, the input channel 510, and the output channel 512 to expose the substrate 306. In aspects, this may aid heat dissipation from the semiconductor dies. Alternatively, the dielectric material 402 may not be etched in this region, or the dielectric material 402 may not be disposed in this region initially.

Although illustrated as being created from the dielectric material 402, portions of the channel 502, the channel 506, the input channel 510, or the output channel 512 may be created from a different material through a different process. For example, surfaces that define the channel 502, the channel 506, the input channel 510, or the output channel 512 may be created from a mold resin. A mold of any of the channels may be provided around the semiconductor dies 302 or the semiconductor dies 304 and the mold resin may be applied around the mold to create the channels. In some cases, the surfaces of the input channel 510 and the output channel 512 that are closest to the edge of the substrate 306 may be created from a mold compound, and the surfaces closest to an interior of the substrate 306 may be created from the dielectric material 402. In some implementations, the input channel 510 and the output channel 512 created between the semiconductor die 302 and the semiconductor die 304 may be created from the mold resin. In aspects, this may enable the input channel 510 or the output channel 512 to extend beyond the back surfaces of the semiconductor die 302 and the semiconductor die 304 (e.g., instead of being created at the back surface of the semiconductor dies as illustrated in FIG. 5B). Thus, portions of the channel 502, the channel 506, the input channel 510, or the output channel 512 may be created through any number of techniques using a variety of materials. Moreover, although the channels are described as being etched in the dielectric material 402, in other embodiments, the dielectric material 402 or the mold resin may be selectively disposed in particular configuration to create the channels without the need for etching.

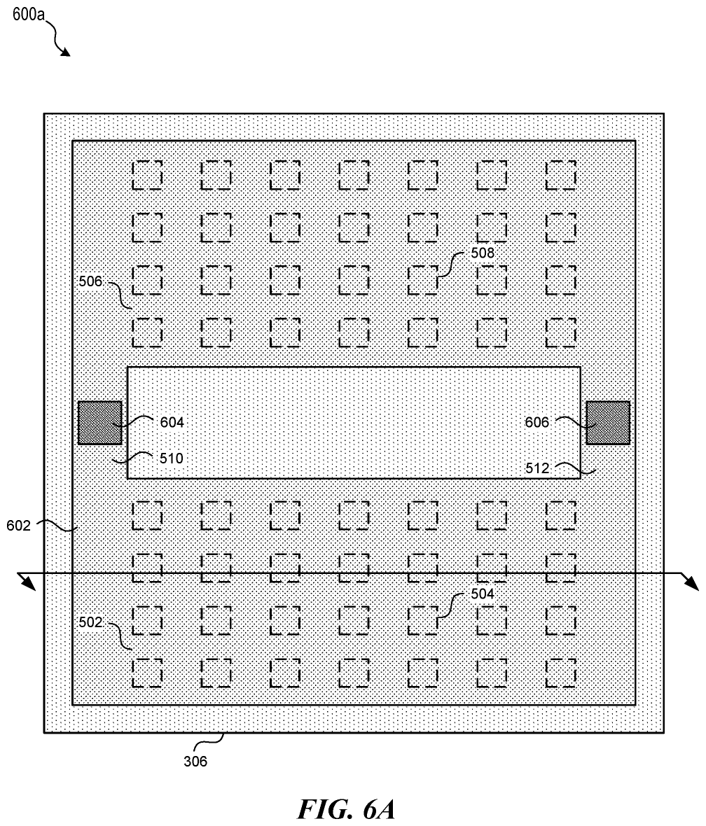

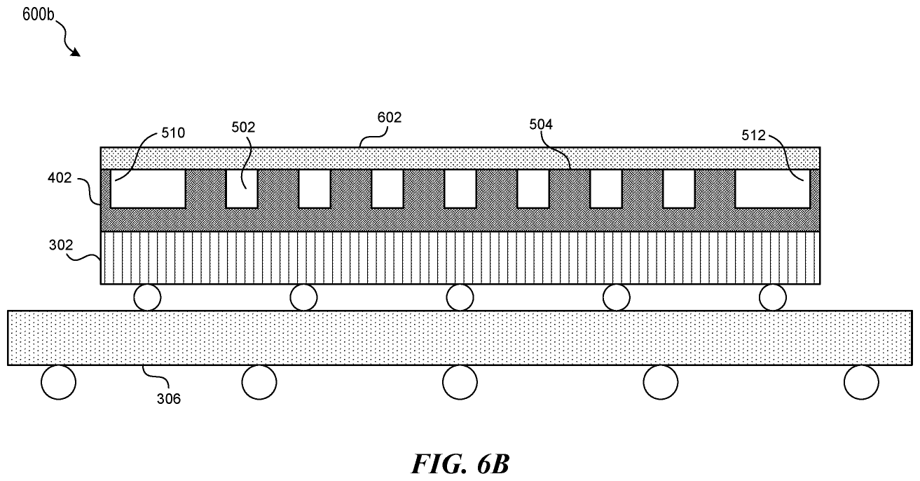

FIGS. 6A and 6B illustrate a stage for enclosing the channels using a lid. Specifically, FIG. 6A illustrates a simplified schematic partial plan view 600a of a semiconductor device assembly in accordance with an embodiment of the present technology, and FIG. 6B illustrates a simplified schematic cross-sectional view 600b (e.g, along the cross-section illustrated in FIG. 6A) of a semiconductor device assembly in accordance with an embodiment of the present technology. A lid 602 may be assembled onto the dielectric material 402 to enclose the channel 502, the channel 506, the input channel 510, or the output channel 512. The lid 602 may be supported by the dielectric material 402 (e.g., at the plurality of structures 504 or the plurality of structures 508 (covered by the lid 602 and illustrated using dotted line in FIG. 6A)). The lid 602 may include a dielectric material such that a direct bond may be created between the lid 602 and the dielectric material 402. In aspects, the lid 602 may include silicon nitride. The lid 602 may form a hermetic seal with the dielectric material 402 to ensure that the fluid flowed through the channels does not leak onto the electronics at the semiconductor device assembly.

The lid 602 may be a shaped lid that corresponds to the channel 502, the channel 506, the input channel 510, and the output channel 512. For example, the lid 602 may not enclose the portion of the substrate 306 exposed between the semiconductor dies. Alternatively, the lid 602 may be a continuous lid that encloses the portion of the substrate 306 between the semiconductor dies, and in some cases, the lid 602 may be etched at this location. The lid 602 may include a first opening that implements an inlet 604 and a second opening that implements an outlet 606. The inlet 604 and the outlet 606 may be etched into the lid 602. The inlet 604 may correspond to the input channel 510. Thus, a fluid input manifold may supply fluid to the packaged semiconductor device through the inlet 604. The input channel 510 may transport the fluid provided through the inlet 604 to the channel 502 or the channel 506. The fluid may flow through the channel 502 or the channel 506 to the output channel 512 where it is expelled through the outlet 606 and provided to a fluid output manifold. Thus, the outlet 606 may correspond to the output channel 512. The inlet 604 and the outlet 606 may be implemented as any appropriate component. For example, the inlet 604 and the outlet 606 may simply be openings in the lid 602. Alternatively, the inlet 604 and the outlet 606 may implement pumps that move fluid into and out of the packaged semiconductor device, respectively.

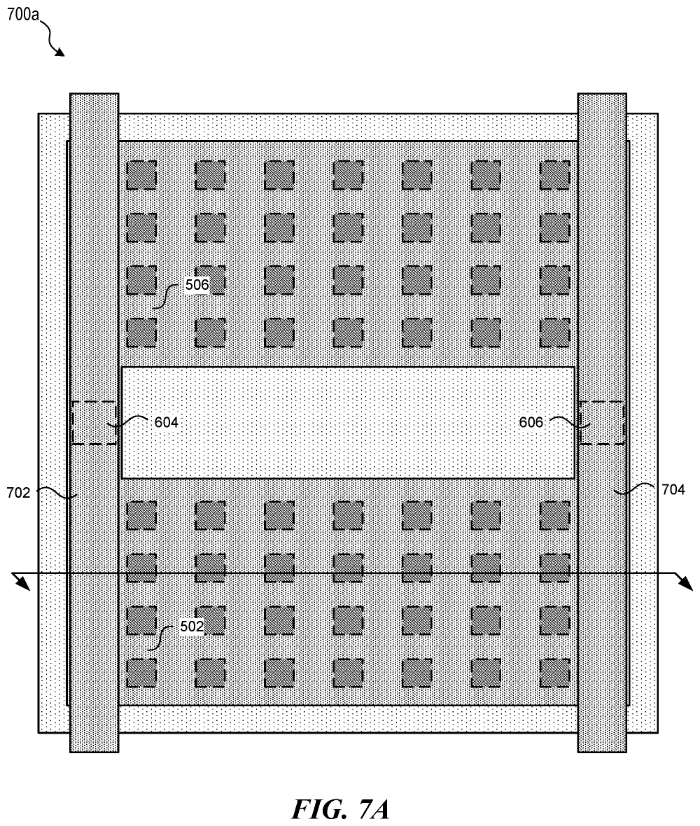

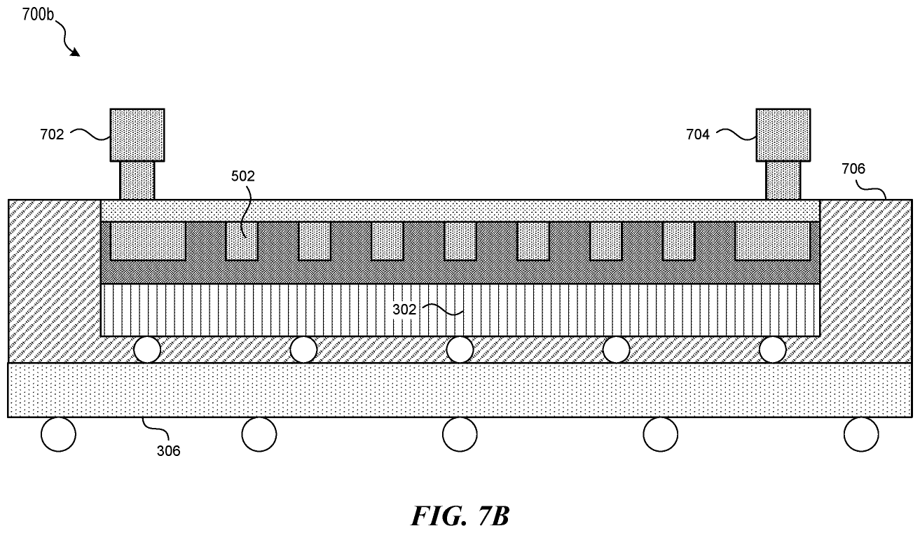

FIGS. 7A and 7B illustrate a stage for coupling the inlet to a fluid input manifold and coupling the outlet to a fluid output manifold. Specifically, FIG. 7A illustrates a simplified schematic partial plan view 700a of a semiconductor device assembly in accordance with an embodiment of the present technology, and FIG. 6B illustrates a simplified schematic cross-sectional view 700b (e.g., along the cross-section illustrated in FIG. 7A) of a semiconductor device assembly in accordance with an embodiment of the present technology. The fluid input manifold 702 may be coupled to the inlet 604 (covered by the fluid input manifold 702 and illustrated using dotted line in FIG. 7A), and the fluid output manifold 704 may be coupled to the outlet 606 (covered by the fluid input manifold 702 and illustrated using dotted line in FIG. 7A). In aspects, the fluid input manifold 702 or the fluid output manifold 704 may be coupled to the inlet 604 or the outlet 606, respectively, and a hermetic seal may be formed to prevent fluid from leaking onto the electronics at the semiconductor device assembly. The fluid input manifold 702 may provide fluid to the channel 502 or the channel 506. The fluid may flow through the channel 502 or the channel 506 where it is provided to the fluid output manifold 704 through the outlet 606. The fluid provided to the fluid output manifold 704 may be heated due to heat transfer from the semiconductor dies to the fluid. The fluid input manifold 702 and the fluid output manifold 704 may be discrete pipelines connected only through channels in the packaged semiconductor dies. Thus, once a fluid is flowed through a channel and heated, it may not be flowed through an additional channel to cool an additional packaged semiconductor device. In this way, the fluid provided for cooling may not be preheated and the temperature of the semiconductor device assembly may be consistently controlled throughout the assembly.

As illustrated in FIG. 7B, the substrate 306 and the semiconductor dies coupled therewith (e.g., semiconductor die 302 or any additional semiconductor die) may be at least partially encapsulated by an encapsulant 706 (e.g., mold resin) to protect the semiconductor device from interferences (e.g., moisture, particulates, static electricity, and physical impact). The substrate 306 and the semiconductor dies may be encapsulated in such a way that the inlet 604 and the outlet 606 are exposed at an exterior of the packaged semiconductor die. In doing so, the fluid input manifold 702 and the fluid output manifold 704 may couple to the inlet 604 and the outlet 606, respectively, to enable fluid to be flowed through the channels in the packaged semiconductor device and cool the device.

This disclosure now turns to details of semiconductor device assemblies that include a cooling system and a plurality of packaged semiconductor devices. Although illustrated in a particular configuration, it should be noted that a semiconductor device assembly that includes a cooling system may include a different number of packaged semiconductor devices, a different type of packaged semiconductor devices, or packaged semiconductor devices arranged in a different configuration.

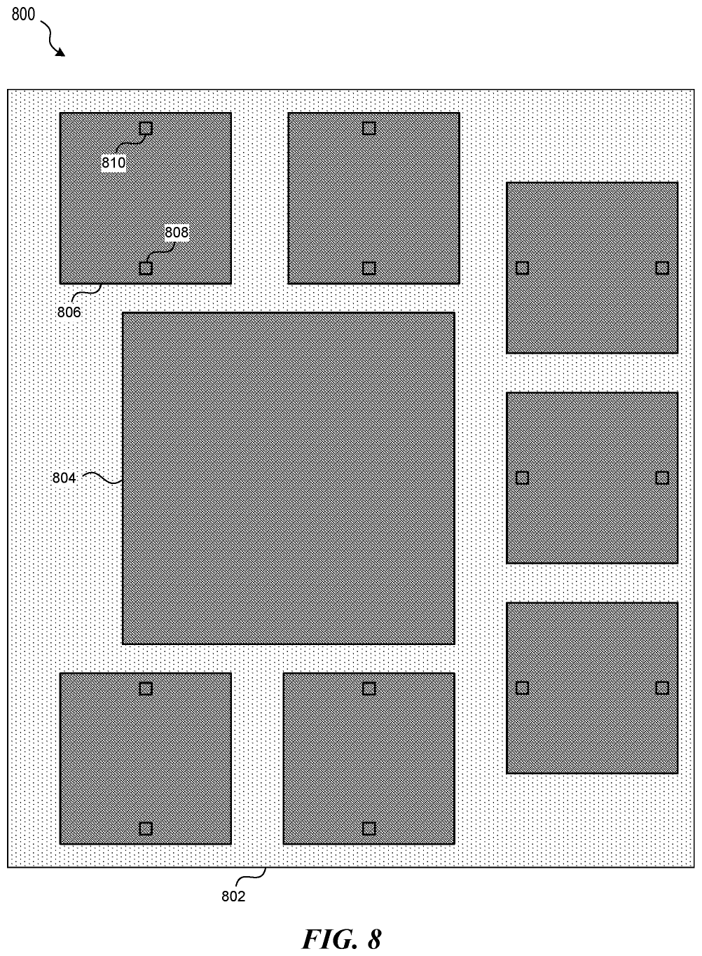

FIG. 8 illustrates a simplified schematic partial plan view of a semiconductor device assembly 800 in accordance with an embodiment of the present technology. The semiconductor device assembly 800 includes a plurality of packaged semiconductor devices assembled onto a substrate 802. The substrate 802 may be a printed circuit board (PCB) or interposer that has circuitry connecting the various components of the semiconductor device assembly 800. In some cases, the plurality of packaged semiconductor devices may include a processor 804 and a plurality of semiconductor devices 806. In aspects, the plurality of semiconductor devices 806 may include memory devices. The semiconductor device assembly 800 may include a device suitable for AI or ML applications. The semiconductor device assembly 800 may include a graphics card, for example, a PCIe graphics card. Each of the plurality of semiconductor devices 806 may include an inlet 808 and an outlet 810 exposed at an exterior of the plurality of semiconductor device 806. The inlet 808 and outlet 810 may provide a location at which fluid is input to and output from the plurality of semiconductor devices 806, respectively, to enable the fluid to be flowed through channels in the plurality of semiconductor devices 806. In aspects, the processor 804 may not include an inlet and an outlet. Instead, the cooling system may include a cold plate that is mounted onto the processor 804 to control the temperature thereat.

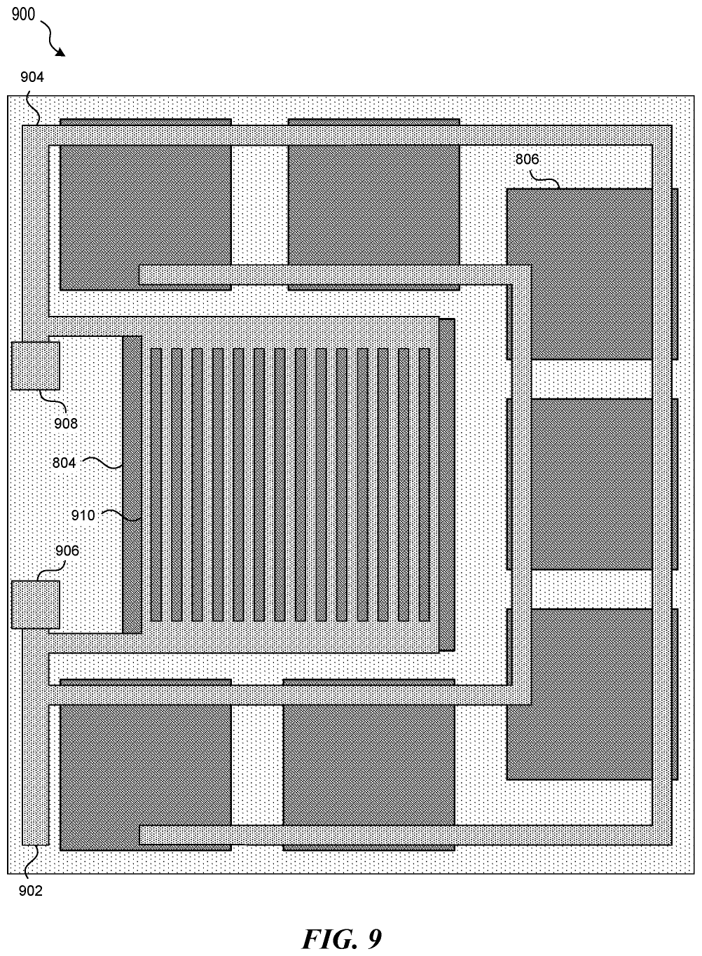

FIG. 9 illustrates a simplified schematic partial plan view of a semiconductor device assembly 900 in accordance with an embodiment of the present technology. The semiconductor device assembly 900 includes a cooling system. The cooling system may include an input manifold 902 coupled to inlets of the plurality of semiconductor devices 806, and an output manifold 904 coupled to outlets of the plurality of semiconductor devices 806. The fluid may be provided to the input manifold 902 through a fluid source 906, and the fluid may be expelled from the output manifold 904 to a fluid sink 908. The input manifold 902 may additionally provide fluid to a cold plate 910 assembled onto the processor 804. The processor 804 may not include an inlet that intakes fluid into the packaged device and an outlet that expels fluid from the packaged device (e.g., like the inlets and outlets on the plurality of semiconductor devices 806). Instead, the cold plate 910 may be assembled onto a surface of the processor 804 at the exterior. The cold plate 910 may include a channel for fluid to be flowed along a surface of the processor 804 to cause heat to transfer from the processor 804 to the fluid. The channel implemented within cold plate 910 may be arranged as parallel flow paths to enable fluid to flow through the cold plate 910 at different locations along the surface of the processor 804. During flowing, the fluid may absorb heat from the processor 804. The heated fluid may be provided to the output manifold 904 to be expelled to the heat sink 908. In this way, the cooling system may regulate the temperature of the semiconductor device assembly 900.

Although in the foregoing example semiconductor device assemblies have been illustrated and described with respect to a particular configuration, in other embodiments, assemblies can be provided with more or less semiconductor devices, different semiconductor devices, or a different configuration of semiconductor devices. Additionally, although some of the packaged semiconductor devices illustrated in and described with respect to FIGS. 1-9 are two-die semiconductor devices, in other embodiments, these packaged semiconductor devices may be single-die packages or multiple-die packages. In this way, the semiconductor devices illustrated in the previous figures may be a variety of other semiconductor devices, mutatis mutandis.

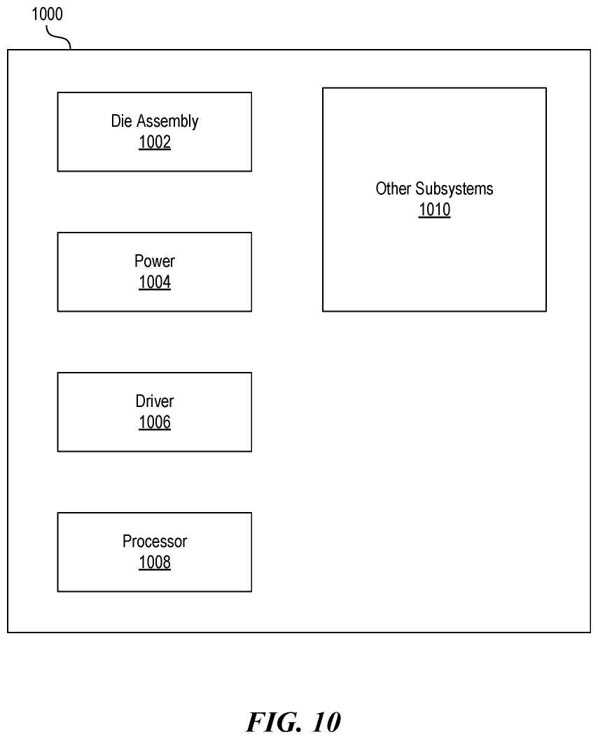

Any one of the semiconductor devices and semiconductor device assemblies described above with reference to FIGS. 2-9 can be incorporated into any of a myriad of larger and/or more complex systems, a representative example of which is system 1000 shown schematically in FIG. 10. The system 1000 can include a semiconductor device assembly (e.g., or a discrete semiconductor device) 1002, a power source 1004, a driver 1006, a processor 1008, and/or other subsystems or components 1010. The semiconductor device assembly 1002 can include features generally similar to those of the semiconductor devices described above with reference to FIGS. 2-9. The resulting system 1000 can perform any of a wide variety of functions, such as memory storage, data processing, and/or other suitable functions. Accordingly, representative systems 1000 can include, without limitation, hand-held devices (e.g., mobile phones, tablets, digital readers, and digital audio players), computers, vehicles, appliances and other products. Components of the system 1000 may be housed in a single unit or distributed over multiple, interconnected units (e.g., through a communications network). The components of the system 1000 can also include remote devices and any of a wide variety of computer readable media.

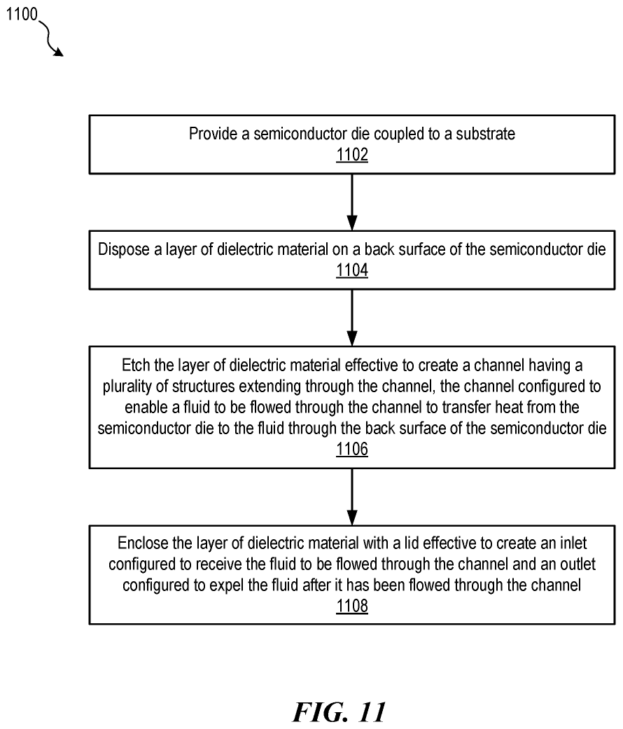

FIG. 11 illustrates an example method 1100 for fabricating a semiconductor device assembly in accordance with an embodiment of the present technology. The method 1100 may, for illustrative purposes, be described with respect to features, components, or elements of FIGS. 2-10. Although illustrated in a particular configuration, one or more operations of the method 1100 may be omitted, repeated, or reorganized. Additionally, the method 1100 may include other operations not illustrated in FIG. 11, for example, operations detailed in one or more other methods described herein.

At 1102, a semiconductor die 302 coupled to a substrate 306 may be provided. The semiconductor die 302 may be coupled on the substrate 306 in a flip-chip arrangement such that a back surface of the semiconductor die 302 faces away from the substrate 306. In some cases, an additional semiconductor die 304 coupled to the substrate 306 may be provided. The semiconductor die 302 or the additional semiconductor die 304 may be a memory die, for example, a GDDR SDRAM die.

At 1104, a layer of dielectric material 402 may be disposed on a back surface of the semiconductor die 302. The layer of dielectric material 402 may be disposed using any number of appropriate techniques, for example, using plasma etching, wet etching, or chemical-mechanical planarization. In some cases, the layer of dielectric material 402 may be disposed at a back surface of the additional semiconductor die 304 or at the substrate 306 between the semiconductor die 302 and the additional semiconductor die 304. In aspects, the layer of dielectric material 402 may include silicon oxide.

At 1106, the layer of dielectric material 402 may be etched to create a channel 502 having a plurality of structures 504 (e.g., arranged in a grid) extending through the channel 506. The channel 502 may be configured to enable a fluid to be flowed through the channel 502 to transfer heat from the semiconductor die 302 to the fluid through the back surface of the semiconductor die 302. The plurality of structures 504 may accelerate a flow of the fluid through the channel 502. In aspects, the plurality of structures 504 may be created from the layer of dielectric material 402. In some cases, the etching may further include etching the layer of dielectric material 402 on a back surface of the additional semiconductor die 304 effective to create an additional channel 506 configured to enable an additional fluid to be flowed through the additional channel 506 to transfer heat from the additional semiconductor die 304 to the additional fluid through the back surface of the additional semiconductor die 304. In some cases, a plurality of structures 508 (e.g., created from the layer of dielectric material 402) may extend through the channel 506 to accelerate the flow of the additional fluid through the channel 506. In some cases, etching the layer of dielectric material 402 may include etching the layer of dielectric material 402 between the semiconductor die 302 and the additional semiconductor die 304 to create an input channel 510 corresponding to an inlet 604 and an output channel 512 corresponding to an outlet 606. The input channel 510 may transport the fluid from the inlet 604 to the channel 502 and transport the additional fluid from the inlet 604 to the channel 506. The output channel 512 may transport the fluid from the channel 502 to the outlet 606 and transport the additional fluid from the additional channel 506 to the outlet 606.

At 1108, the layer of dielectric material 402 may be enclosed with a lid 602 effective to create an inlet 604 configured to receive the fluid to be flowed through the channel 502 and an outlet 606 configured to expel the fluid after it has been flowed through the channel 502. The lid 602 may be supported by the layer of dielectric material 402 (e.g., at the plurality of structures 504). The lid 602 may include a first opening and a second opening to implement the inlet 604 and the outlet 606. The inlet 604 and the outlet 606 may be etched in the lid 602. The lid 602 may include a dielectric material, for example, silicon nitride. The lid 602 may be bonded to the layer of dielectric material 402 to create a hermetic seal to prevent fluid from leaking out from the channel 502. The inlet 604 may be configured to receive the additional fluid to be flowed through the additional channel 506. The outlet 606 may similarly be configured to expel the additional fluid after it has been flowed through the additional channel 506. In some cases, the method 1100 may further include coupling the inlet 604 to an input manifold 702 configured to provide the fluid to be flowed through the channel 502 and coupling the outlet 606 to an output manifold 704 configured to receive the fluid after it has been flowed through the channel 502. In this way, a compact and effective cooling system for a semiconductor device may be implemented.

Specific details of several embodiments of semiconductor devices, and associated systems and methods, are described above. The suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a processor or memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a substrate;
a semiconductor die assembled onto the substrate;
a layer of dielectric material disposed on a back surface of the semiconductor die, the layer of dielectric material defining a channel configured to enable a fluid to flow through the channel and cause heat to be transferred from the semiconductor die to the fluid through the back surface of the semiconductor die, the layer of dielectric material including a plurality of structures extending through the channel effective to accelerate a flow of the fluid through the channel;
an inlet configured to receive the fluid to be flowed through the channel; and
an outlet configured to expel the fluid after it has been flowed through the channel.

2. The semiconductor device assembly of claim 1, further comprising:
an additional semiconductor die assembled onto the substrate; and
an additional layer of dielectric material disposed on a back surface of the additional semiconductor die, the additional layer of dielectric material defining an additional channel configured to enable additional fluid to flow through the additional channel and cause heat to be transferred from the additional semiconductor die to the additional fluid through the back surface of the additional semiconductor die,
wherein the inlet is configured to receive the additional fluid to be flowed through the additional channel, and
wherein the outlet is configured to receive the additional fluid after it has been flowed through the additional channel.

3. The semiconductor device assembly of claim 2, further comprising:
an input channel configured to:
transport the fluid from the inlet to the channel; and
transport the additional fluid from the inlet to the additional channel; and
an output channel configured to:
transport the fluid from the channel to the outlet; and
transport the additional fluid from the additional channel to the outlet.

4. The semiconductor device assembly of claim 3, further comprising another layer of dielectric material disposed at the substrate between the semiconductor die and the additional semiconductor die, the other layer of dielectric material defining the input channel and the output channel.

5. The semiconductor device assembly of claim 1, wherein the plurality of structures are disposed in a grid.

6. The semiconductor device assembly of claim 1, wherein the channel is enclosed by a lid that is supported by the plurality of structures.

7. The semiconductor device assembly of claim 6, wherein:
the inlet is configured to receive the fluid through a first opening in the lid; and
the outlet is configured to expel the fluid through a second opening in the lid.

8. The semiconductor device assembly of claim 6, wherein the lid comprises silicon nitride.

9. A method of making a semiconductor device assembly, comprising:
providing a semiconductor die coupled to a substrate;
disposing a layer of dielectric material on a back surface of the semiconductor die;
etching the layer of dielectric material effective to create a channel having a plurality of structures extending through the channel, the channel configured to enable a fluid to be flowed through the channel to transfer heat from the semiconductor die to the fluid through the back surface of the semiconductor die, the plurality of structures effective to accelerate a flow of the fluid through the channel; and
enclosing the layer of dielectric material with a lid effective to create an inlet configured to receive the fluid to be flowed through the channel and an outlet configured to expel the fluid after it has been flowed through the channel.

10. The method of claim 9, further comprising:
providing an additional semiconductor die coupled to the substrate;
disposing the layer of dielectric material on a back surface of the additional semiconductor die; and
etching the layer of dielectric material on the back surface of the additional semiconductor die effective to create an additional channel configured to enable an additional fluid to be flowed through the additional channel to transfer heat from the additional semiconductor die to the additional fluid through the back surface of the additional semiconductor die,
wherein the inlet is configured to receive the additional fluid to be flowed through the additional channel, and
wherein the outlet is configured to expel the additional fluid after it has been flowed through the additional channel.

11. The method of claim 10, further comprising:
disposing the layer of dielectric material on the substrate between the semiconductor die and the additional semiconductor die; and
etching the layer of dielectric material on the substrate between the semiconductor die and the additional semiconductor die to create:
an input channel corresponding to the inlet and effective to:
transport the fluid from the inlet to the channel; and
transport the additional fluid from the inlet to the additional channel; and
an output channel corresponding to the outlet and effective to:
transport the fluid from the channel to the outlet; and
transport the additional fluid from the additional channel to the outlet.

12. The method of claim 9, further comprising:
coupling the inlet to an input manifold configured to provide the fluid to be flowed through the channel; and
coupling the outlet to an output manifold configured to receive the fluid after it has been flowed through the channel.

13. The method of claim 9, wherein the plurality of structures are arranged in a grid.

14. A semiconductor device assembly, comprising:
an input manifold configured to provide fluid to be flowed through a plurality of channels;
an output manifold configured to expel the fluid after it has been flowed through the plurality of channels, the input manifold and the output manifold connected only through the plurality of channels;
a processor die;
a first channel of the plurality of channels, the first channel disposed at the processor die and configured to receive a first portion of the fluid from the input manifold and provide the first portion of the fluid to the output manifold after it has been flowed through the first channel; and
a plurality of semiconductor die packages, each semiconductor die package including:
at least one semiconductor die; and
a second channel of the plurality of channels, the second channel disposed at the at least one semiconductor die and configured to receive a second portion of the fluid from the input manifold and provide the second portion of the fluid to the output manifold after it has been flowed through the second channel.

15. The semiconductor device assembly of claim 14, wherein the input manifold is configured to provide more of the fluid to the first channel than the second channel.

16. The semiconductor device assembly of claim 14, wherein each semiconductor die package further includes one or more structures extending through the second channel effective to accelerate a flow of the second portion of the fluid through the second channel.

17. The semiconductor device assembly of claim 14, wherein each semiconductor die package further includes:
an inlet coupled to the input manifold and configured to receive the second portion of the fluid from the input manifold to be flowed through the second channel; and
an outlet coupled to the output manifold and configured to provide the second portion of the fluid to the output manifold after it has been flowed through the second channel.

18. The semiconductor device assembly of claim 14, wherein the semiconductor device assembly comprises a Peripheral Component Interconnect Express (PCIe) graphics card.

19. The semiconductor device assembly of claim 14, wherein the at least one semiconductor die comprises two semiconductor dies laterally spaced semiconductor dies.

20. The semiconductor device assembly of claim 14, wherein the semiconductor device assembly has a thermal resistance less than 0.05 degrees Celsius per Watt.
